(19) United States
(12) Patent Application Publication
(10) Pub. No.: US 2005/0219084 A1
(43) Pub. Date: Oct. 6, 2005

(54) Integrated circuit with parallel-serial converter

(75) Inventors: Stefan Dietrich, Turkenfeld (DE); Thomas Hein, Munchen (DE); Peter Schroegmeier, Munchen (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 11/089,039

(22) Filed: Mar. 25, 2005

(30) Foreign Application Priority Data
Mar. 26, 2004 (DE) 10 2004 014 968.2

(51) Int. Cl. H03M 9/00

(52) U.S. Cl. 341/101

(57) ABSTRACT

Integrated circuit with a parallel-serial converter The invention relates to an integrated circuit and method for time-offset provision of input data for a parallel-serial converter, in particular for or in a DDR semiconductor memory, having at least n input terminals at which at least n data packets are present in parallel, a delay device arranged in a manner connected downstream of the input terminals, at least some of the data packets present on the input side being output in time-offset fashion with respect to one another by said delay device, a parallel-serial converter arranged in a manner connected downstream of the delay device, which parallel-serial converter performs a conversion of the data packets that are present in parallel and are time-offset with respect to one another into an output data signal comprising the time-offset data packets in serial form, and an output terminal for outputting the output data signal.

### CLAIM FOR PRIORITY

This application claims priority to German Application No. 10 2004 014 968.2, filed Mar. 26, 2004, which is incorporated herein, in its entirety, by reference.

### TECHNICAL FIELD OF THE INVENTION

The invention relates to an integrated circuit for time-offset provision of input data for a parallel-serial converter, and to a method for operating such an integrated circuit.

### BACKGROUND OF THE INVENTION

In modern computer and software applications there is increasingly a demand for ever larger volumes of data to be processed in an ever shorter time. Large scale integrated memories, such as DRAM memories for example, are used for storing the data. In order, then, to meet the aforementioned demand for an ever higher speed when processing data, it is necessary, in the case of such a semiconductor memory, for said data to be written to the memory and read out from said memory again appropriately rapidly.

As development advances in the field of integrated circuits, the operating frequency thereof rises, too, so that the data can be processed appropriately rapidly.

What is more, semiconductor memories also exist which are specially designed for high data rates. One representative of such a semiconductor memory is the so-called DDR-DRAM memory, where DDR stands for “double data rate”. Whereas in conventional semiconductor memories write and read operations are performed only upon the rising edge or the falling edge of a clock signal, in DDR semiconductor memories data are read out from the semiconductor memory and written to the semiconductor memory again both upon the rising edge and upon the falling edge of the clock signal. A double data rate is thus realized. In the case of these DDR-DRAM memories, a plurality of memory addresses are simultaneously accessed internally, and their data contents are then output successively. The data read out from the semiconductor memory are initially present in parallel internally and have to be converted, for the purpose of outputting said data, by means of a parallel-serial converter in order then to be output as serial data.

FIG. 1 shows a known circuit arrangement for reading out data from a semiconductor memory 1 by means of a parallel-serial converter and FIG. 2 shows the corresponding timing diagram for this conversion operation. The method for reading out and serializing data from the semiconductor memory 1 is described below on the basis of a so-called prefetch-4 access, in the course of which the memory cells of four internal addresses are accessed simultaneously and the data DQ0-DQ3 stored therein are read out. A “prefetch” read access is to be understood to mean that a plurality of data packets are always read out simultaneously from the memory cell array. The data DQ0-DQ3 read out in parallel in this way are fed to a FIFO 2 connected downstream of the semiconductor memory 1. Said FIFO 2 serves for setting the read latency, which denotes the time for reading out the data from the semiconductor memory 1. At an instant dependent on the read latency, the four data packets DQ0-DQ3 are simultaneously read out from the FIFO 2 and fed to a parallel-serial converter 3 connected downstream. The parallel-serial converter 3 converts the data packets DQ0-DQ3 present in parallel on the input side into an output signal OUT.

Control signals RI0, RI1, FA0, FA1 derived from the system clock CLK are provided for this conversion. In terms of their time sequence, the signals RI0, RI1, FA0, FA1 correspond to the succession of the serial data that are to be output at the output of the parallel-serial converter 3. For the conversion of the data, the parallel-serial converter 3 has a number of inverters corresponding to the number of data packets DQ0-DQ3 present in parallel, the individual data packets DQ0-DQ3 present in parallel being written successively to said inverters. Each inverter is assigned a multiplexer which is driven by means of the signals RI0, RI1, FA0, FA1. In this case, the signals RI0, RI1, FA0, FA1 drive said multiplexer in such a way that the data packets DQ0-DQ3 present in parallel are output temporally successively onto a common output line 4. In this case, each inverter requires a sufficiently long set-up time and hold time in order also to be able to read out all data from the respectively assigned data packet DQ0-DQ3. Ideally, the set-up time and hold time amounts to approximately half a clock cycle of the system clock CLK, that is to say td=CLK/2. This duration td is typically predetermined by the specification of a semiconductor memory and must not be violated. If this requirement is not fulfilled or is fulfilled only to an inadequate degree, that is to say if a sufficiently long set-up time and hold time is not available to the inverters of the parallel-serial converter 3, then the duration available for latching the data would become too short. This has the consequence that a data eye 7 that is intended to include the latched data, after the serialization of the data, is narrower than the requisite half a clock cycle and thus less than the duration td.

The problem arises in this case that with the ever higher operating frequency, ever higher clock rates are available for the semiconductor memory 1 and the parallel-serial converter 3. The higher the clock rates used for operating the parallel-serial converter 3, the more difficult it becomes, however, to obtain the optimum width td of the data eyes 7. FIGS. 3a and 3b illustrate this problem.

FIGS. 3a and 3b in each case show an enlarged excerpt from the timing diagram of FIG. 2. In the cases of the example shown in FIG. 3a, the problem of an excessively short data eye would result for the first data eye 7a, which is assigned to the signal RI0, and for the last data eye 7b, which is assigned to the signal FA1. The data in the corresponding data packet only become valid at the instant at which the inverter driven by the signal RI0 is opened. However, the data already become invalid again as soon as the inverter driven by the signal FA1 is closed. In the case of the inverters driven with these two control signals RI0, FA1, problems can therefore arise when latching the data and thus for the generation of the respective data eyes 7a, 7b since an excessively short set-up and hold time is available to the corresponding inverters.

By contrast, if the data are latched with the rising edge of the control signals RI0, RI1, FA0, FA1, as is illustrated in FIG. 3b, then the problem of insufficiently wide data eyes can only be partly solved. If the data, then, are latched with the rising edge of the control signals RI0, RI1, FA0, FA1, it is necessary for the timing of the signal RI0 to be correspondingly time-offset with respect to the data packets DQ0-DQ3 in order to provide for a sufficient set-up time of the inverters. In this case, however, the hold time for the inverter assigned to the signal FA1 is almost zero (see FIG. 3b). If the signals are shifted in relation to one another and the falling edges of the signals RI0, RI1, FA0, FA1 are utilized for latching the data, then the problem arises, however, with regard to the set-up time of the inverter assigned to the signal RI0.

In order to resolve this conflict, at the present time use is made of asynchronous delay stages which, however, are accompanied by an additional outlay on circuitry. What is particularly disadvantageous about the use of such asynchronous delay stages, primarily, is that they are greatly process-, temperature- and voltage-dependent. When latching the data read out, these process, temperature and voltage fluctuations have the effect that the data eyes are occasionally greatly deformed or are too short in this case. It is to be expected, therefore, that the problems described above will increasingly be exacerbated further in the case of future semiconductor memories operated at ever higher operating frequencies and ever lower operating voltages.

### SUMMARY OF THE INVENTION

The present invention discloses, in the context of the parallel-to-serial conversion of data packets, output signals with an optimum data width of the serial data contained therein.

According to one embodiment of the invention, there is an integrated circuit for time-offset provision of input data for a parallel-serial converter, in particular for or in a DDR semiconductor memory, having at least n input terminals at which at least n data packets are present in parallel, a delay device arranged in a manner connected downstream of the input terminals, at least some of the data packets present on the input side being output in time-offset fashion with respect to one another by the delay device, a parallel-serial converter arranged in a manner connected downstream of the delay device, which parallel-serial converter performs a conversion of the data packets that are present in parallel and are time-offset with respect to one another into an output data signal comprising the time-offset data packets in serial form, having an output terminal for outputting the output data signal.

In another embodiment of the invention, there is a method for operating such an integrated circuit, having—
provision of n data packets present in parallel at the input terminals;
delaying of at least some of the parallel data packets in such a way that, after the delaying, there is a predeterminable time offset between at least some of the data packets among one another;
parallel application of the data packets that are generated in this way and are time-offset with respect to one another to the parallel-serial converter;
conversion of the data packets that are present in parallel and are time-offset with respect to one another in accordance with their temporal sequence in order to generate an output signal in which the data are present in serial fashion.

In the present invention, the data packets that are read out in parallel from the cell array of the semiconductor memory being provided in time-offset fashion at the input of the parallel-serial converter. For this purpose, there is connected upstream of the parallel-serial converter a device which temporally influences the respective data packets in accordance with the desired requirement in such a way that a temporal offset is present between individual data packets or groups of data packets. The fact, then, that the various data packets are present in time-offset fashion with respect to one another means that the problem of the insufficient hold and set-up time for the provision of a data eye having a predetermined width is eliminated or at least significantly reduced.

Any arbitrary device that affords a corresponding functionality can be used for the device according to the invention which serves for generating a temporal offset of the individual data packets. The invention is particularly advantageous, however, if the aforesaid functionality for providing a time offset is implemented by a FIFO connected upstream of the parallel-serial converter. This is particularly advantageous since a FIFO is connected upstream of the parallel-serial converter anyway in the case of a memory designed as an SDRAM semiconductor memory, which FIFO then merely has to be slightly extended in terms of its functionality in order to ensure the desired time offset in the case of the parallel data packets provided by the FIFO on the output side.

Advantages of a circuit arrangement according to the invention and of a method according to the invention for operating the circuit arrangement are apparent:

Firstly, the time-offset supply of data packets present in parallel at the output of the FIFO according to the invention guarantees that the data read out in parallel from the semiconductor memory are serialized without any problems. It is thus advantageously possible to provide exact data eyes, that is to say data eyes having the optimum, predetermined width, that is to say the duration of half a clock cycle of the system clock.

What is more, the method according to the invention and thus also the corresponding circuit arrangements according to the invention can likewise be used very reliably at very high frequencies. The method according to the invention and the circuit arrangement according to the invention are therefore suitable in particular in an advantageous manner for future memory generations operated at increasingly higher frequencies of 500 MHz through to the GHz range.

The circuit arrangement according to the invention and the method according to the invention furthermore increase the robustness of the semiconductor memory toward technology fluctuations which are typically present anyway and which will set in particularly in the case of future memory generations, which will exhibit an ever higher scale of integration and in which there will thus be an ever smaller feature size.

The invention is also particularly robust toward voltage and/or temperature fluctuations.

The delay device, according still another embodiment of the invention, advantageously has a control device, which can be used to set, relative to a fixedly predetermined time reference, a defined time offset for at least some of the data packets. The control device may have, in the simplest case, a counter which predetermines the defined time offset by means of its counter reading and thus generates at least two different groups of output pointers. A time offset desired for a respective data packet can thus be predetermined in each case by means of the counter reading of the counter. A ring counter is particularly advantageously suitable here as the counter.

The invention is also suitable in particular for semiconductor memories designed as SDRAM memories since a FIFO memory is present in this case anyway. Said FIFO is in this case arranged between the read outputs of the semiconductor memory and the input terminals of the parallel-serial converter connected downstream. The FIFO can advantageously equally be utilized in a highly advantageous manner for generating the time offset for the in the case of the data packets present in parallel. In order to realize this functionality according to the invention, said FIFO merely has to be slightly modified, which entails a small additional outlay on circuitry, however. The delay device according to the invention advantageously has a FIFO that can be controlled by the control device.

According to yet another embodiment of the invention, at least two groups of output pointers by means of which a FIFO cell of the controllable FIFO can be driven are provided by means of the device according to the invention for generating a time offset. By means of different output pointers, the corresponding data packets can be arranged in time-offset fashion with respect to one another. For this purpose, the FIFO has an input pointer, a first output pointer and at least one further output pointer that is different from the first output pointer, it being possible for the temporal offset to be predetermined by means of a respective output pointer or the interval separating them.

In an advantageous manner, the first and the at least one further output pointer and thus the at least one predeterminable time offset are set by means of the counter reading of the counter.

Typically, precisely two different output pointers and two groups of the data packets are provided. In this case, a respective one of the output pointers is assigned to one of the groups of the data packets.

Typically, the predeterminable time offset is chosen such that it lies in the range of 0.5-1.5 times the duration of a clock cycle of the system clock.

In a typical configuration of the invention, the parallel-serial converter is designed as a controllable shift register, which converter has a number of controllable latches corresponding to the number of data packets. Such a controllable latch typically has a number of inverters corresponding to the number of inputs. The use of tristate inverters is particularly advantageous since, with the tristate inverters, in addition to the two typical output levels (“0” or low, “1” or high), it is also possible to provide a high-impedance, so-called tristate state at the output of the tristate inverter.

In an advantageous embodiment, the individual data packets are in each case time-offset in pairs. In addition or as an alternative, it may also be provided that in each case two different groups of data packets are provided, which are time-offset with respect to one another.

The predetermined time offset is typically set by means of a counter operated relative to a fixed reference. The setting of the predetermined time offset is controlled by means of the counter with the aid of the various output pointers.

In this case, the determination of the individual time offsets, in particular the duration and the number of the time offsets required, depends in particular on the duration of an individual data packet. Moreover, these variables also depend on the number of data packets present in parallel.

### BRIEF DESCRIPTION OF THE DRAWINGS

The invention is explained in more detail below on the basis of the exemplary embodiments specified in the schematic figures of the drawings, in which:

FIG. 1 shows a block diagram of a known read-out operation for reading out data from a semiconductor memory using a parallel-serial converter.

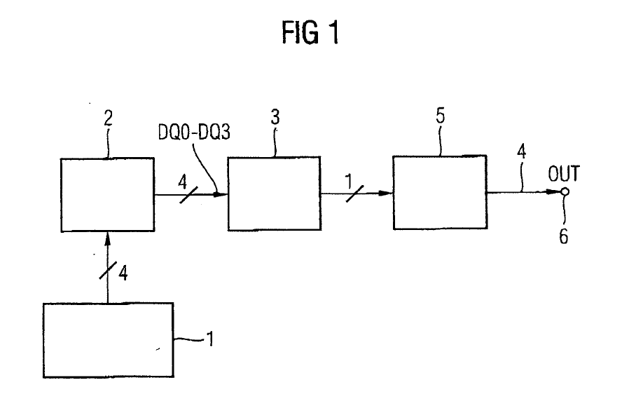

FIG. 2 shows a timing diagram of the clock, data and control signals present at the parallel-serial converter in FIG. 1.

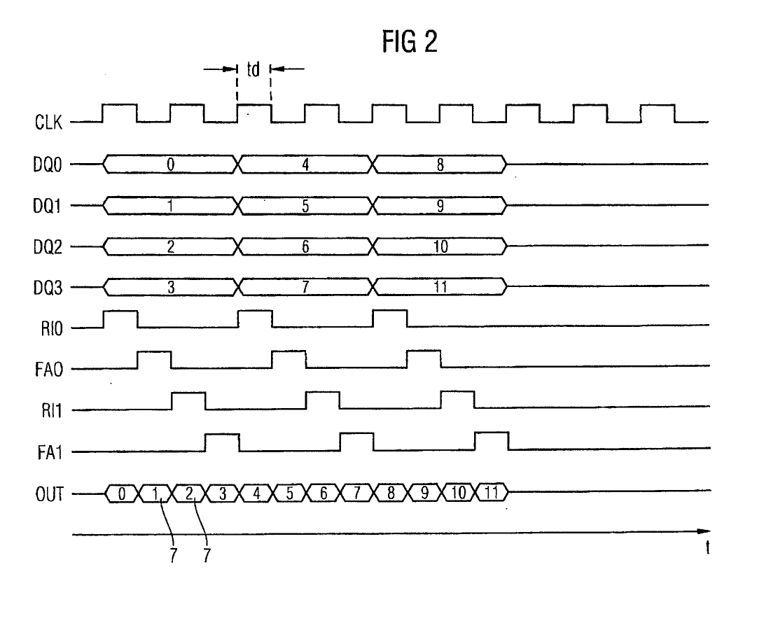

FIG. 3 shows two excerpts from the timing diagram from FIG. 2 for illustrating a conflict when latching the data.

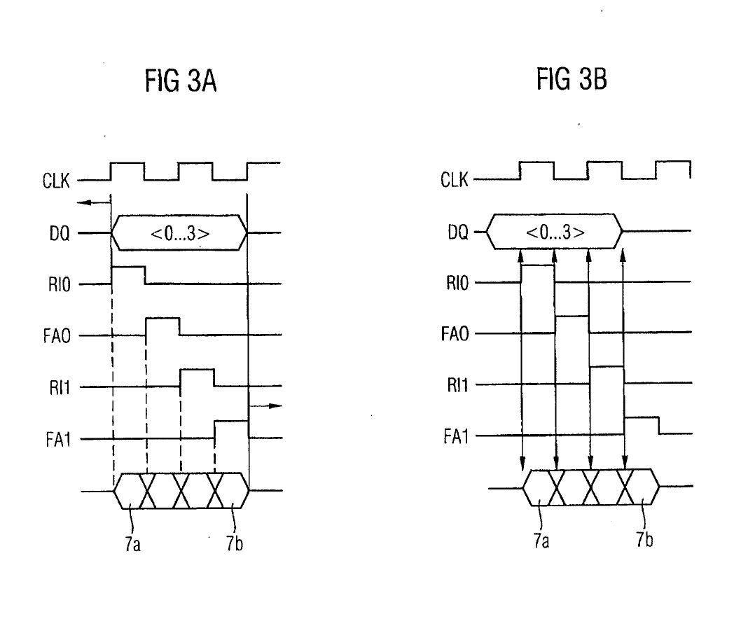

FIG. 4 shows a block diagram of a circuit arrangement according to the invention for reading out data from a semiconductor memory using a parallel-serial converter.

FIG. 5 shows a timing diagram of the clock, data and control signals present on the input side at the parallel-serial converter in FIG. 4, the parallel data packets being present in time-offset fashion in the case of the signals.

FIG. 6 shows a block diagram of a multistage FIFO according to the invention for the provision of time-offset data packets.

FIG. 7 shows a timing diagram for illustrating the time-offset data packets provided by the FIFO according to the invention in accordance with FIG. 6.

FIG. 8 shows a timing diagram for illustrating the method according to the invention for generating time-offset data packets by means of a plurality of time-offset output pointers.

FIG. 9 shows the detailed circuitry construction of a FIFO according to the invention for providing time-offset data packets on the output side.

In the figures of the drawings, identical or functionally identical elements, data and signals are provided with the same reference symbols, unless specified otherwise.

### DETAILED DESCRIPTION OF THE INVENTION

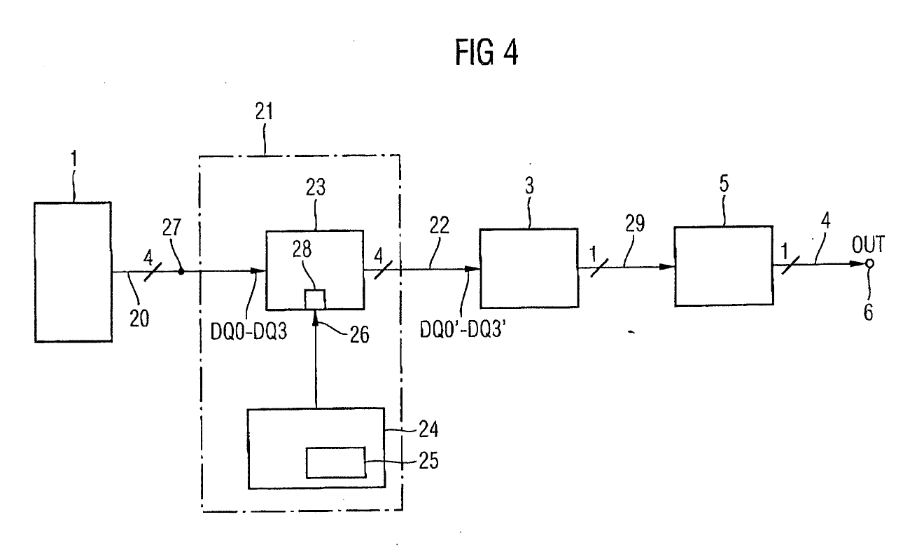

FIG. 4 shows a block diagram of a circuit arrangement according to the invention for reading out data from a semiconductor memory using a parallel-serial converter.

In this case, a semiconductor memory, for example a DDR-SDRAM semiconductor memory, is designated by reference symbol 1 in FIG. 4. The construction and the method of operation of such a semiconductor memory 1 are generally known, and so this will not be discussed in any greater detail below. It should merely be pointed out that such a semiconductor memory has a memory cell array with a multiplicity of memory cells. For reading and writing, data lines are provided via which data can be written to the memory cell array and can be read out therefrom. In the present exemplary embodiment, 32-bit-wide data words are read out from the memory cell array during a read operation. Said data words are in each case split into four groups of eight bits. Each of these groups is referred to as a data packet below.

It shall be assumed below that four data packets DQ0-DQ3 each of 8 bits are read out by means of a so-called prefetch-4 read access to the semiconductor memory. In this case, the duration of a data packet DQ0-DQ3 corresponds to the duration of two clock cycles of the system clock CLK. This also corresponds to the applicable specification for DDR-SDRAM semiconductor memories produced at the present time. Such a read-out operation in which 32 bits are read out simultaneously is generally also referred to as a data burst or as a “burst” for short.

The semiconductor memory 1 is connected via data lines 20 to an input 27 of a device 21 according to the invention for providing time-offset data, connected downstream. For the purpose of outputting the data read out, the four parallel data packets DQ0′-DQ3′ are fed via data lines 22 to an output circuit in the form of a parallel-serial converter 3, the output circuit being controlled by a system clock CLK. In the simplest case, a parallel-serial converter 3 is designed as a controllable shift register having, by way of example, a number of controllable inverters connected in parallel corresponding to the number of input terminals 27. The construction and the method of operation of such a parallel-serial converter designed as a controllable shift register are known in many instances and described for example in Kories, Schmidt-Walter, Taschenbuch der Elektrotechnik [Pocketbook of Electrical Engineering], Wissenschaftlicher Verlag Harri Deutsch GmbH, 5^{th} corrected edition, 2003. On the output side, the parallel-serial converter is connected via a single data line 29 to an OCD output driver 5, which connects the parallel-serial converter 3 to the output 6.

During a normal read operation, read data are output simultaneously on all 32 data terminals of the semiconductor memory. The parallel-serial converter has to latch the data in the four parallel data packets DQ0′-DQ3′ at a so-called “strobe” instant. For this purpose, the parallel-serial converter 3 correspondingly has four inverters (not shown in FIG. 4) in the case of which so-called set-up and hold times have to be complied with for latching the data.

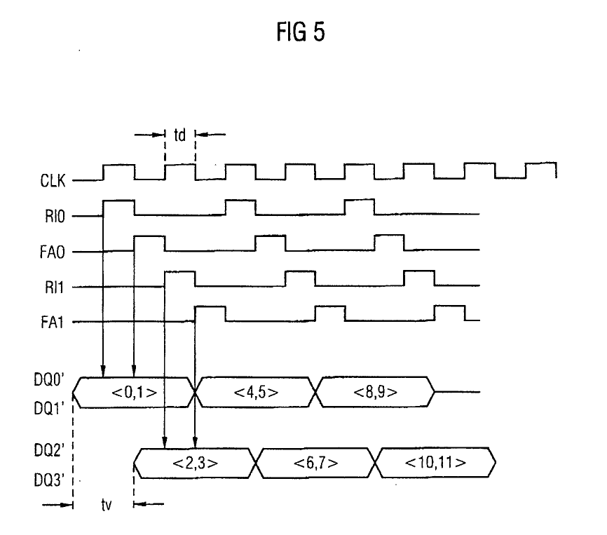

When a read command, for example a prefetch-4 read command, is present, data DQ0-DQ3 are read out in parallel from the cell array of the semiconductor memory 1 and made available to the device 21 in parallel via the data lines 20. Said data DQ0-DQ3 are read into the device 21. From the data DQ0-DQ3 present in parallel on the input side, the device 21 generates, according to the invention, output-side data DQ0′-DQ3′ which are arranged in time-offset fashion with respect to one another and are fed to the parallel-serial converter 3 connected downstream. The parallel-serial converter 3 is now able to latch the data DQ0′-DQ3′ which, although still present in parallel on the input side, are present in time-offset fashion with respect to one another (see FIG. 5). Since the data DQ0′-DQ3′ are also present in time-offset fashion, a sufficient set-up time and hold time for the corresponding inverters is now also present for latching the data DQ0′-DQ3′. The data eyes which are obtained in this way by latching the data DQ0′-DQ3′ present in parallel in time-offset fashion thus also have the optimum width—predetermined in accordance with the specification—of half a clock duration td=CLK/2. These data eyes are then provided successively in serial form and output as the output signal OUT. By means of the output driver 5, said output signal OUT with the serial data contained therein is transmitted via the read line 4 and the output 6.

The device 21 has a FIFO 23, which is configured according to the invention and is driven by means of a suitable control device 24. The control device 24 serves the purpose of providing corresponding output pointers 26 for the FIFO 23 according to the invention, which pointers can be used to generate the time offset tv for the generation of the time-offset data signals DQ0′-DQ3′.

For this purpose, the control device 24 has a simple counter 25, for example an up-counter, which can be used to provide different output pointers 26 which drive a control terminal 28 of the FIFO 23.

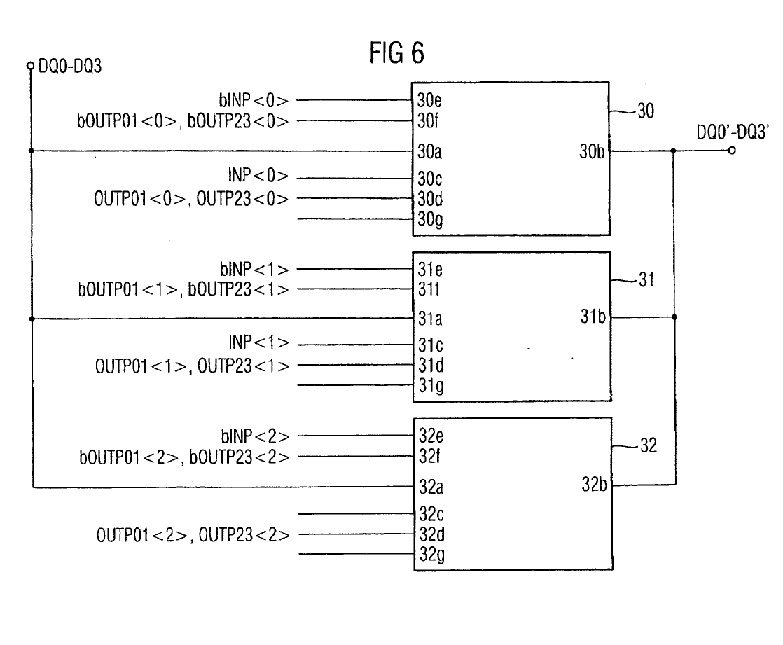

The precise construction and the method of operation of the device 21 according to the invention for providing a time offset and, in particular, of the FIFO 23 according to the invention are described in detail below with reference to FIGS. 6-9.

FIG. 6 shows the construction of a FIFO 21 according to the invention on the basis of a block diagram. In FIG. 6, the numerals in the angle brackets in each case relate to the significance of the data packets DQ0-DQ4 that are coupled in successively. In this case, the FIFO 21 according to the invention is designed as a three-stage FIFO and therefore has three FIFO cells 30-32 which serve for processing three successive data packets DQ0-DQ3.

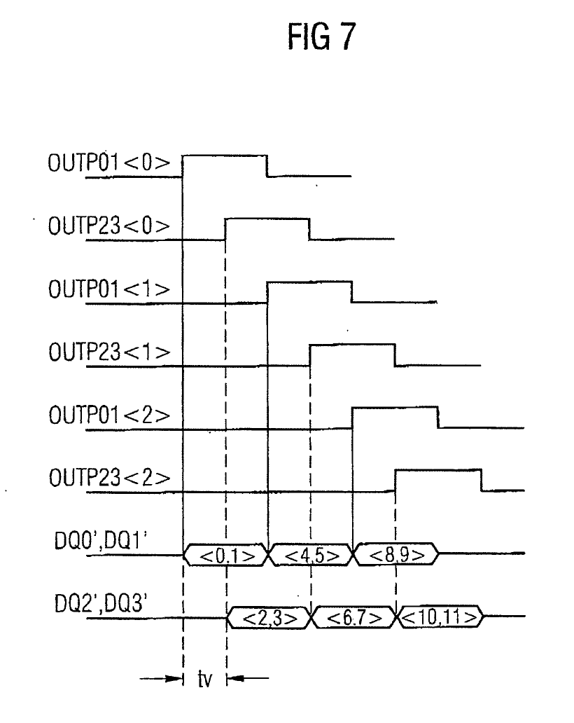

Each FIFO cell 30-32 in each case has a plurality of data inputs 30a-32a—in the present case respectively four data inputs—and also an identical number of data outputs 30b-32b. The corresponding data packets DQ0-DQ3 can be read into the individual FIFO cells 30-32 via the data inputs 30a-32a. Each FIFO cell 30-32 furthermore has in each case two further input terminals 30c-32c, 30d-32d. Input pointers INP for a respective FIFO cell 30-32 are coupled into the input terminals 30c-32c in a known manner. Output pointers OUTP01, OUTP23 modified according to the invention are then coupled into the respective other input terminals 30d-32d. In this case, different output pointers OUTP01, OUTP23 are provided for different data packets DQ0-DQ3. Consequently, different groups of output pointers OUTP01, OUTP23 are defined depending on the number of data packets DQ0-DQ3 present. It shall be assumed in the present exemplary embodiment that four different data packets DQ0-DQ3 are present. Two different groups of output pointers OUTP01, OUTP23 are provided for said four data packets DQ0-DQ3. In this case, the output pointer OUTP01 is assigned to the data packets DQ0, DQ1, whereas the output pointer OUTP23 is assigned to the respective data packets DQ2, DQ3 (see FIG. 7). FIG. 7 uses a schematic timing diagram to show the generation of time-offset data packets DQ0-DQ3 in a manner dependent on the different output pointers OUTP01, OUTP23.

The different groups of output pointers OUTP01, OUTP23 can be generated in a very simple manner by means of the signals RI0, RI1, FA0, FA1. For this purpose, the signals RI0, RI1, FA0, FA1, which in each case designate a read access, will use for triggering a FIFO counter 25 (see FIG. 4). In this case, the FIFO counter 25 is designed such that it switches back and forth between the respective output pointers OUTP01 and OUTP23 depending on its respective counter reading. The major advantage in the case of this use according to the invention of different groups of output pointers OUTP01, OUTP23 consists in the fact that the transition from one data packet DQ0′-DQ3′ to the next no longer has any effect whatsoever on the data eyes generated when latching the data.

Particularly when using tristate inverters within the FIFO cells 30-32, the latter furthermore have further inputs 30e-32e, 30f-32f via which corresponding input pointers bINP and, respectively, groups of output pointers bOUTP01, bOUTP23 can be coupled in in inverted form. Furthermore, input terminals 30g-32g are provided via which a respective FIFO cell 30-32 can be switched on or have a supply potential applied to it.

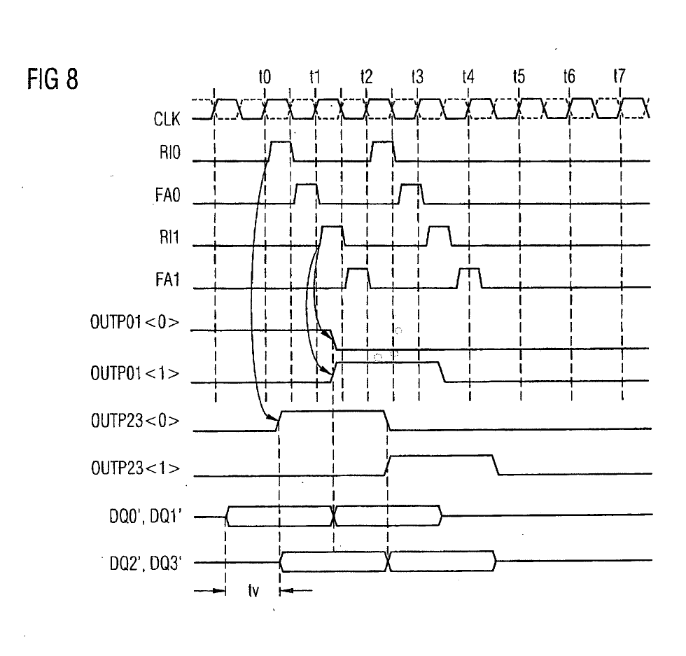

FIG. 8 shows a timing diagram illustrating not only the control signals RI0, FA0, RI1, FA1 but also the system clock CLK and the output pointers OUT01, OUTP23. The signals RI0, RI1, FA0, FA1 are derived from the system clock CLK, the designation “RI” denoting latching with the rising edge and the designation “FA” denoting latching with the falling clock edge of the clock signal CLK. The signals RI0, RI1, FA0, FA1 are more or less clock-synchronous with the system clock CLK in FIG. 8. It is evident that the output pointers OUTP23 are arranged in time-offset fashion relative to the output pointers OUTP01, thus giving rise to two groups of the data packets DQ0′, DQ1′; DQ2′, DQ3′ that are time-offset with respect to one another. The control signals RI0, FA0 thus lie temporally in the range of the data packets DQ0′, DQ1′, so that, taking account of the set-up time and hold time, the data can be latched without any problems for the duration of said data packets DQ0′, DQ1′. The same holds true with regard to the control signals RI1, FA1 and the time-offset data packets DQ2′, DQ3′.

Two groups of output pointers OUTP01, OUTP23 are provided in the present exemplary embodiment, that is to say in the case of four data packets DQ0-DQ3 present in parallel. As an alternative, it is also possible for more than two different output pointer types to be provided in the case of more than four data packets DQ0-DQ3 present in parallel. Furthermore, it would also be conceivable for an output pointer assigned to each data packet DQ0-DQ3 to be provided in each case for a data packet DQ0-DQ3. It has been assumed in the present exemplary embodiment that the different data packets DQ0-DQ3 are in each case assigned in pairs to one of the output pointers OUTP01, OUTP23.

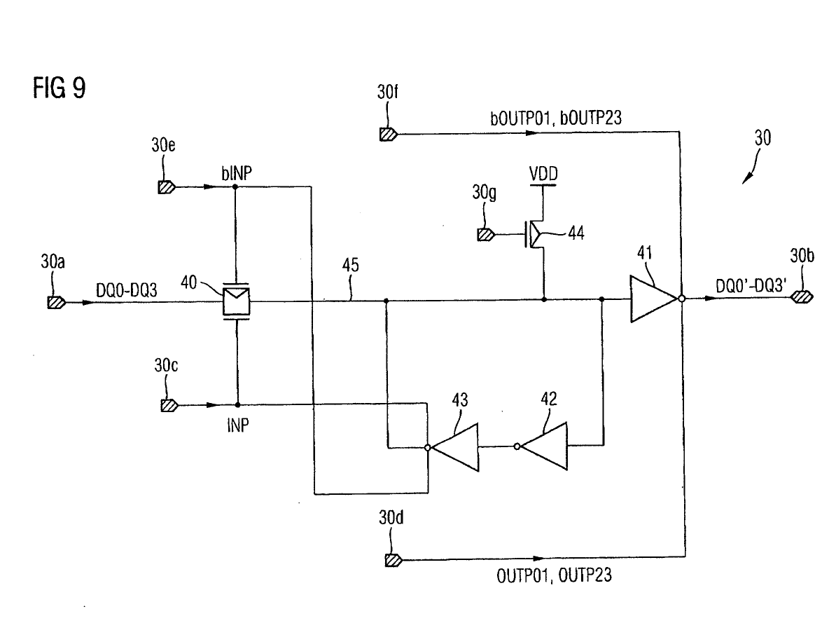

FIG. 9 uses a circuit diagram to show the detailed construction of a typical FIFO cell in accordance with FIG. 6.

A transfer gate 40 is arranged between the input 30a and the output 30b of the FIFO cell 30, the respective parallel data packets DQ0-DQ3 being fed to the transfer gate. On the output side, the transfer gate 40 is connected to a tristate inverter 41, which is in turn coupled to the output 30b on the output side. Via the input terminals 30c, 30e, the control terminals of the transfer gate 40 can be driven with the corresponding input pointers INP, bINP. The input terminals 30d, 30f serve for driving the output-side tristate inverter 41 with the output pointers OUTP01, OUTP23, bOUTP01, bOUTP23. Furthermore, a feedback loop containing an inverter 42 and also a tristate inverter 43 connected downstream of said inverter 42 is provided between the transfer gate 40 and the output inverter 41. Said tristate inverter 43 is likewise driven by means of the input pointers INP, bINP. Furthermore, a controllable switch 44, for example a MOSFET transistor, is provided, which can be driven via the input terminal 30g. Given suitable driving, it is thus possible to apply a supply potential VDD to the data path 45 between transfer gate 40 and output inverter 41.

According to the invention, different groups of output pointers OUTP01, OUTP23 are coupled into the FIFO cell 30 via the input terminals 30d, 30f, so that the output-side tristate inverter 41 is in each case driven with different output pointers OUTP01, OUTP23. The consequence of this is that a time offset is generated in the case of the data packets DQ0′-DQ3′ provided at the output of the FIFO cell 30.

Although the present invention has been described above on the basis of a preferred exemplary embodiment, it is not restricted thereto, but rather can be modified in diverse ways.

In particular, in the present exemplary embodiment, the device according to the invention for generating a time offset for the data packets has deliberately been illustrated in a very simple manner, but without restricting the invention in this respect. Moreover, the invention shall not be restricted to the concrete construction of a FIFO according to the invention as described above. Rather, it is possible to provide FIFO circuits altered through corresponding modification. By way of example, tristate inverters also need not necessarily be provided for the FIFO cells, rather conventional inverters may, of course, also be used in this case.

The invention has furthermore been described by way of example on the basis of a so-called DDR-DRAM semiconductor memory. However, the invention shall not be exclusively restricted thereto, but rather can likewise advantageously be used in arbitrary applications in which data present in parallel are intended to be converted into a serial signal. It goes without saying that the invention can also be extended to other semiconductor memories.

Moreover, a so-called prefetch-4 read access in which four data packets each having eight bits are read out in each case need not necessarily be provided. Fewer or more data packets per read access would also be conceivable. Furthermore, a respective data packet also need not necessarily comprise precisely eight bits or a data word, but rather may have correspondingly more or fewer bits.

List of Reference Symbols

1 (DDR-SDRAM) semiconductor memory
2 FIFO, FIFO memory
3 Parallel-serial converter
4 Output line
5 (OCD) output driver
6 Output
7, 7a, 7b Data eyes
20 Data lines
21 Device for generating a time offset
22 Data lines
23 FIFO
24 FIFO control device
25 FIFO counter
26 Input/output pointers
27 Input terminal
28 Control terminal
29 Data line
30-32 FIFO cells
30a-32a Data inputs
30b-32b Data outputs
30c-32c Inputs for input pointers
30d-32d Inputs for output pointers
30e-32e Inputs for inverted input pointers
30f-32f Inputs for inverted output pointers
30g-32g Inputs for switching on the FIFO cells
40 Transfer gate
41 Tristate inverter
42 Inverter
43 Tristate inverter
44 Controllable switch, MOSFET
45 Data line
DQ0-DQ3 Data packets (present in parallel)
DQ0′-DQ3′ Data packets (present in parallel, in time-offset fashion)
OUT Output signal
CLK Clock signal, system clock
RI0, RI1 Control signal for latching
FA0, FA1 Control signal for latching
OUTP01 Output pointers
OUTP23 Output pointers
pOUTP01 Inverted output pointers
pOUTP23 Inverted output pointers
INP Input pointers
pINP Inverted input pointers
VDD Positive supply potential
t1-t7 Instants
td Duration of a data eye
tv Time offset

1. An integrated circuit for time-offset provision of input data for a parallel-serial converter for or in a DDR semiconductor memory, comprising:
at least n input terminals at which at least n data packets are present in parallel;
a delay device arranged in a manner connected downstream of the input terminals, at least some of the data packets present on an input side being output in time-offset fashion with respect to one another by the delay device;
a parallel-serial converter arranged in a manner connected downstream of the delay device, which parallel-serial converter performs a conversion of the data packets that are present in parallel and are time-offset with respect to one another into an output data signal comprising the time-offset data packets in serial form; and
an output terminal for outputting the output data signal.

2. The circuit according to claim 1, wherein the delay device has a control device which provides a control signal that can be used to set, relative to a fixedly predetermined time reference, a defined temporal time offset for at least some of the data packets present in parallel.

3. The circuit according to claim 2, wherein the control device has a ring counter by means of which the defined temporal offset can be predetermined.

4. The circuit according to claim 1, wherein the delay device has a controllable FIFO, which is connected to the input terminals on the input side and to an input of the parallel-serial converter on the output side and which has a control terminal, by means of which it is possible to set a defined time offset for at least some of the data packets present in parallel.

5. The circuit according to claim 4, wherein the FIFO has an input pointer, a first output pointer and at least one further output pointer that is different from the first output pointer, it being possible for the temporal offset to be predetermined by means of a respective one of the output pointers.

6. The circuit according to claim 5, wherein the first and the at least one further output pointer and the at least one predeterminable time offset can be set by means of the counter reading of the counter.

7. The circuit according to claim 1, wherein two different output pointers and two groups of the data packets are provided, a respective one of the output pointers being assigned to one of the groups of the data packets.

8. The circuit according to claim 1, wherein the temporal offset between the output pointers varies in a range of 0.5 to 1.5 times a clock duration of a system clock signal.

9. The circuit according to claim 1, wherein the parallel-serial converter is designed as a controllable shift register and has a number of controllable latches corresponding to the number n.

10. The circuit according to claim 1, wherein at least one controllable latch has a tristate inverter.

11. A method for operating an integrated circuit, comprising:
providing n data packets present in parallel at input terminals;
delaying at least some of the parallel data packets such that, after the delaying, there is a predetermined time offset between at least some of the data packets among one another;
applying, in parallel, the data packets that are generated and are time-offset with respect to one another to the parallel-serial converter;
converting the data packets that are present in parallel and are time-offset with respect to one another in accordance with a temporal sequence to generate an output signal in which the data are present in serial fashion.

12. The method according to claim 11, wherein the data packets are time-offset in pairs.

13. The method according to claim 11, wherein the predetermined time offset is set by means of a counter operated relative to a fixed reference.

14. The method according to claim 11, wherein the predetermined time offset is controlled by means of a first and at least one further output pointer.

15. The method according to claim 11, wherein duration of an individual data eye and/or the number n of data packets present in parallel are taken into account for determining the individual time offsets.
